(19) United States
(12) Patent Application Publication
(10) Pub. No.: US 2018/0138221 A1
(43) Pub. Date: May 17, 2018

(54) WAFER LEVEL PACKAGING STRUCTURE OF HIGH-PIXEL IMAGE SENSOR CHIP

(71) Applicant: HUATIAN TECHNOLOGY (KUNSHAN) ELECTRONICS CO., LTD., Kunshan (CN)

(72) Inventors: Lixi WAN, Kunshan (CN); Min XIANG, Kunshan (CN); Lingling ZHAI, Kunshan (CN); Jingxian QIAN, Kunshan (CN); Li MA, Kunshan (CN)

(21) Appl. No.: 15/822,247

(22) Filed: Nov. 27, 2017

Related U.S. Application Data
(63) Continuation of application No. PCT/CN2015/090912, filed on Sep. 28, 2015.

(30) Foreign Application Priority Data
May 18, 2015 (CN) 201520320946.6

(51) Int. Cl. H01L 27/146; H01L 23/48

(52) U.S. Cl. CPC H01L 27/14618; H01L 23/481; H01L 27/14636

(57) ABSTRACT

A wafer level packaging structure of a high-pixel image sensor chip comprises an image sensor chip, a supporting substrate and a light-transmitting substrate, the image sensor chip comprises a base, a sensing region formed on a first surface of the base; the supporting substrate is attached to the first surface of the base and provided with a first opening penetrating through the supporting substrate at a position corresponding to the sensing region, and the sensing region is exposed from a bottom of the first opening; and the light-transmitting substrate is fixed on a first surface plane of the supporting substrate and covers a top of the first opening, and two surface planes of the light-transmitting substrate are parallel with a plane on which the sensing region is located.

### CROSS-REFERENCE TO RELATED APPLICATIONS

The present application is a continuation of International Patent Application No. PCT/CN2015/090912 filed on Sep. 28, 2015, which claims priority to Chinese Patent Application No. 201520320946.6, filed on May 18, 2015, all contents of which are incorporated by reference herein.

### TECHNICAL FIELD

Embodiments of the present invention relate to packaging of an image sensor chip, more particularly to a wafer level packaging structure of a high-pixel image sensor chip.

### BACKGROUND

In a packaging structure of a high-pixel image sensor chip, a light-transmitting substrate needs to be fixed on a supporting substrate, and contact surfaces between the light-transmitting substrate and the supporting substrate need to be parallel with the sensing region as much as possible to ensure that the light-transmitting substrate is in parallel with the sensing region, so that good optical performances can be achieved. However, the fixing of the light-transmitting substrate is complicated in the process of wafer level packaging, and optical performances also need to be further improved.

### SUMMARY

Embodiments of the present invention are directed toward a wafer level packaging structure of a high-pixel image sensor chip, which is simple in structure, and can improve optical performances as well as reliability of the packaging structure.

A wafer level packaging structure of a high-pixel image sensor chip according to the embodiments of the present invention comprises an image sensor chip, a supporting substrate and a light-transmitting substrate, the image sensor chip comprises a base, a sensing region formed on a first surface of the base; the supporting substrate is attached to the first surface of the base and provided with a first opening penetrating through the supporting substrate at a position corresponding to the sensing region, and the sensing region is exposed from a bottom of the first opening; and the light-transmitting substrate is fixed on a first surface plane of the supporting substrate and covers a top of the first opening, and two surface planes of the light-transmitting substrate are parallel with a plane on which the sensing region is located.

In an embodiment of the present invention, the light-transmitting substrate has a planar size larger than the first opening and smaller than the first surface plane of the supporting substrate.

In an embodiment of the present invention, the light-transmitting substrate is made of IR optical coated glass.

In an embodiment of the present invention, side walls of the first opening are sloping.

In an embodiment of the present invention, a top size of the first opening is smaller than a bottom size of the first opening.

In an embodiment of the present invention, a dihedral angle of the side walls of the first opening and the plane on which the sensing region is located is greater than or equal to 40° and less than 90°.

In an embodiment of the present invention, a top size of the first opening is larger than a bottom size of the first opening.

In an embodiment of the present invention, a dihedral angle of the side walls of the first opening and the plane on which the sensing region is located is greater than 90° and less than or equal to 130°.

In an embodiment of the present invention, the supporting substrate is made of silicon.

In an embodiment of the present invention, a thickness of the supporting substrate is in the range of 100 μm˜500 μm.

In an embodiment of the present invention, the supporting substrate further comprises a second surface plane which is opposite to the first surface plane of the supporting substrate, and the second surface plane of the supporting substrate is pasted on the first surface of the base by glue.

In an embodiment of the present invention, wafer level packaging structure further comprises at least one vent slot, the at least one vent slot is carved on the first surface plane of the supporting substrate and connects the first opening and an edge space of the supporting substrate.

In an embodiment of the present invention, wafer level packaging structure further comprises at least one semi-closed channel penetrating the edge of the supporting substrate, the at least one semi-closed channel is formed at a periphery of the first surface plane of the supporting substrate and connected to the at least one vent slot.

In an embodiment of the present invention, the image sensor chip further comprises multiple welding pads which are located at a periphery of the sensing region, and the welding pads and the sensing region are electrically connected through internal metal wiring.

In an embodiment of the present invention, the image sensor chip further comprises a dielectric layer formed on the first surface of the base, and the sensing region and the welding pads are disposed in the dielectric layer.

In an embodiment of the present invention, the dielectric layer is made of silicon oxide, silicon nitride or silicon oxynitride.

In an embodiment of the present invention, wafer level packaging structure further comprises channels, an insulating layer and a metal wiring layer, the channels are formed in a second surface of the base and expose the welding pads, the insulating layer is formed on the channels and the second surface of the base and exposes the welding pads, and the metal wiring layer is formed on the insulating layer and exposed surfaces of the welding pads and electrically leads the welding pads to the second surface of the base.

In an embodiment of the present invention, wafer level packaging structure further comprises a protection layer, the protection layer is formed on the metal wiring layer.

In an embodiment of the present invention, the insulating layer is made of a high-molecular polymeric material, silicon oxide, silicon nitride or silicon oxynitride; the metal wiring layer is made of Al, Ni, Au, Cu, Ti, Pt or any combination thereof; and the protection layer is made of a high-molecular polymeric material.

In an embodiment of the present invention, wafer level packaging structure further comprises one or more second openings and welding balls which are disposed in preset positions of the protection layer, the welding balls are connected to the metal wiring layer.

In the wafer level packaging structure of a high-pixel image sensor chip according to the embodiments of the present invention, the supporting substrate generally has the first surface plane and the second surface plane which are parallel or approximately parallel with each other, which can ensure that the plane of the supporting substrate on which the light-transmitting substrate is placed is smooth. Therefore, when the light-transmitting substrate is fixed on the supporting substrate, the requirement that contact surfaces of the light-transmitting substrate and the supporting substrate need to be parallel or nearly parallel with the plane of the sensing area as much as possible can be realized, so that the two surface planes of the light-transmitting substrate can be parallel or nearly parallel with the plane of the sensing region, and the optical performances of the packaging structure are improved. In addition, the first opening can be formed by only one etching processing, which is simple in the packaging processing.

### BRIEF DESCRIPTION OF DRAWINGS

The above and other aspects of the present invention will become more apparent from the following detailed description when taken in conjunction with the accompanying drawings in which:

FIG. 1 is a schematic diagram illustrating a wafer level packaging structure of a high-pixel image sensor chip according to an embodiment of the present invention;

FIG. 2 is a schematic diagram illustrating an amplified structure at section A in FIG. 1;

FIG. 3 is a schematic diagram illustrating a matching structure of a wafer level packaging structure of a high-pixel image sensor chip and lens according to an embodiment of the present invention;

FIG. 4 is a schematic diagram illustrating abase back interconnection of a wafer level packaging structure of a high-pixel image sensor chip according to an embodiment of the present invention; and

FIG. 5 is a schematic diagram illustrating a wafer level packaging structure of a high-pixel image sensor chip according to another embodiment of the present invention.

### DETAILED DESCRIPTION

In the following detailed description, embodiments will be described with reference to the accompanying drawings. However, the present invention may be embodied in various different forms, and should not be construed as being limited only to the illustrated embodiments. Rather, these embodiments are provided as examples, simply by way of illustrating the concept of the present invention to those skilled in the art. Accordingly, processes, elements, and techniques that should be apparent to those of ordinary skill in the art are not described herein.

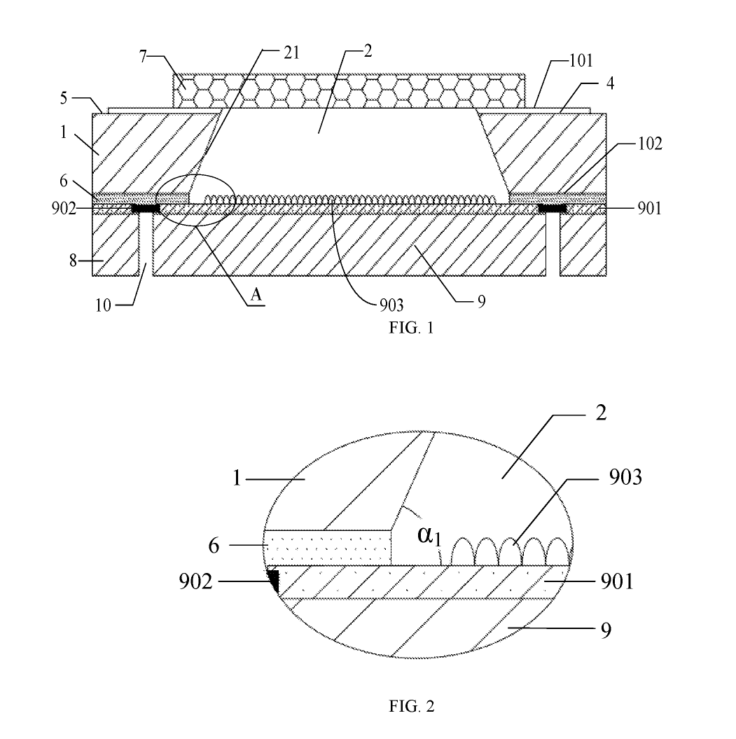

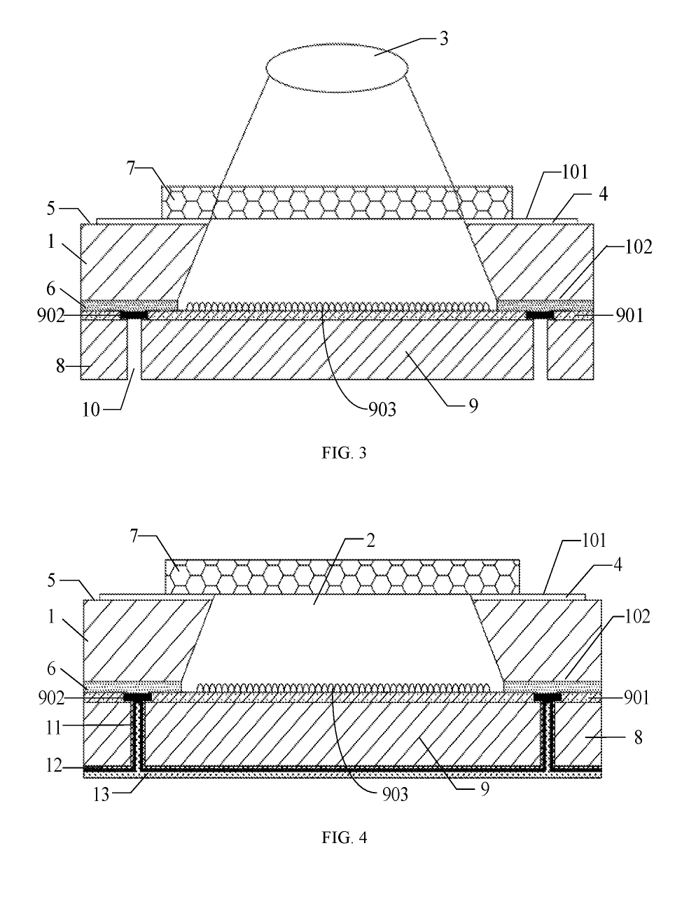

FIG. 1 is a schematic diagram illustrating a wafer level packaging structure of a high-pixel image sensor chip according to an embodiment of the present invention, and FIG. 2 is a schematic diagram illustrating an amplified structure at section A in FIG. 1.

As shown in FIGS. 1 and 2, the wafer level packaging structure of a high-pixel image sensor chip comprises an image sensor chip 9, a supporting substrate 1 and a light-transmitting substrate 7. The image sensor chip 9 includes a base 8 and a sensing region 903 formed on a first surface of the base 8. The supporting substrate 1 is attached to the first surface of the base 8. In a specific embodiment, the supporting substrate 1 has a first surface plane 101 and a second surface plane 102 opposite thereto, and the second surface plane 102 of the supporting substrate 1 is pasted on the first surface of the base 8, for example, they can be bonded together by glue 6. The supporting substrate 1 is provided with a first opening 2 penetrating through the supporting substrate 1 at a position corresponding to the sensing region 903, and the sensing region 903 is exposed from a bottom of the first opening 2. The first opening 2 can be formed by a dry etching or a wet etching, and the wet etching includes anisotropic etching. The first opening 2 may be formed by one etching processing. The light-transmitting substrate 7 is fixed on the first surface plane 101 of the supporting substrate 1 and covers a top of the first opening 2, and two surface planes of the light-transmitting substrate 7 are parallel or approximately parallel with a plane on which the sensing region 903 is located.

In an embodiment of the present invention, the supporting substrate 1 is made of silicon.

It is known that the problem that a plane of the step and a plane on which the sensing region is located are not parallel with each other may occur by forming a step inside the supporting substrate to place the light-transmitting substrate. In the wafer level packaging structure of a high-pixel image sensor chip according to the embodiment of the present invention, the supporting substrate 1 is formed by cutting a silicon wafer or a ground and thinned silicon wafer after the completion of packaging, thus it generally has the first surface plane 101 and the second surface plane 102 which are parallel or approximately parallel with each other, which can ensure that the plane of the supporting substrate 1 on which the light-transmitting substrate 7 is placed is smooth. Therefore, when the light-transmitting substrate 7 is fixed on the supporting substrate 1, the requirement that contact surfaces of the light-transmitting substrate 7 and the supporting substrate 1 need to be parallel or nearly parallel with the plane of the sensing area 903 as much as possible can be realized, so that the two surface planes of the light-transmitting substrate 7 can be parallel or nearly parallel with the plane of the sensing region 903, and the purpose of improving the optical performances of the packaging structure can be achieved.

In addition, a gap between the sensing region 903 and the light-transmitting substrate 7 may be ensured to meet requirements of a high-pixel image sensor chip by setting a silicon supporting substrate, and the large gap can reduce the influence of particles of the light-transmitting substrate 7 on the sensing region 903. The first opening 2 can be formed by only one etching processing, which is simple in the packaging processing.

Preferably, the light-transmitting substrate 7 is Infrared Radiation (IR) optical coated glass, such as IR filter glass, which can block the transmission of infrared light and improve the optical performances of the image sensor.

In an embodiment of the present invention, the light-transmitting substrate 7 is a segmented monolithic substrate, and it has a planar size larger than the first opening 7 and smaller than the first surface plane 101 of the supporting substrate 1. Thus in the process of wafer level manufacturing, the monolithic light-transmitting substrate 7 may be pasted on the first surface plane 101 of the supporting substrate 1 which is made of silicon wafer smoothly.

Preferably, side walls of the first opening 2 are not perpendicular to the plane on which the sensing region 903 is located, that is, the side walls of the first opening 2 are sloping, the top size of the first opening 2 is larger than the bottom size of the first opening 2, or the top size of the first opening 2 is smaller than the bottom size of the first opening 2.

In a specific embodiment of the present invention, as shown in FIG. 1, the top size of the first opening 2 is smaller than the bottom size. Since the top of the first opening 2 is narrow, the size of the light-transmitting substrate 7 may be small, and the area of the first surface plane 101 of the supporting substrate 1 not covered by the light-transmitting substrate 7 becomes large, which increases free degree of the fixed position of the light-transmitting substrate 7. On the other hand, the bottom of the first opening 2 is wide, and the bottom edge of the first opening 2 is far away from the sensing region 903, which may improve the situation that the glue 6 for bonding overflows into the sensing region 903 when the supporting substrate 1 is bonded with the image sensor chip 9, thus the reliability is increased.

Preferably, referring to FIGS. 2 and 3, a dihedral angle α₁ of side walls 21 of the first opening 2 and the plane on which the sensing region 903 is located is in the range of 40°≤α₁<90°. It is known that a lens 3 is placed on the top of the packaging structure of the high-pixel image sensor chip, and ambient light passes through the lens 3 and the light-transmitting substrate 7 and enters the space of the first opening 2 with a certain range of angles. In a preferred embodiment of the present invention, the side walls 21 of the first opening 2 are designed to exactly match with the angles range of the incident light of the lens 3.

Preferably, the thickness of the supporting substrate 1 is in the range of 100 μm˜500 μm. In this way, a large gap between the sensing region 903 and the light-transmitting substrate 7 can be realized, which reduces the influence from particles of the light-transmitting substrate 7 on the sensing region 903. The conjunction of the thickness of the supporting substrate 1 and the inclination of the side walls 21 of the first opening 2 may reduce some undesirable phenomena such as ghost, dazzle light of the high-pixel image sensor chip, or the like.

Preferably, at least one vent slot 4 connecting the first opening 2 and the edge space of the supporting substrate 1 is carved on the first surface plane 101 of the supporting substrate 1. In the process of chip packaging, the first opening 2 is not sealed, and the purpose of setting the vent slot 4 is to balance the atmospheric pressure inside and outside the first opening 2 in the vacuum environment.

More preferably, at least one semi-closed channel 5 penetrating the edge of the supporting substrate 1 is formed at the periphery of the first surface plane 101 of the supporting substrate 1. The semi-closed channels 5 is connected to the vent slot 4, which brings a better effect on the balance of the atmospheric pressure inside and outside the first opening 2.

Multiple welding pads 902 are disposed at the periphery of the sensing area 903, and the welding pads 902 and the sensing region 903 are electrically connected through internal metal wiring. Preferably, the image sensor chip 9 further comprises a dielectric layer 901 which is formed on the first surface of the base 8, and the sensing region 903 and the welding pads 902 are disposed in the dielectric layer 901.

In an embodiment of the present invention, the sensing region 903 of the high-pixel image sensor chip has 5 million pixels or more. The base 8 is made of a semiconductor material such as silicon, gallium arsenide, etc. The dielectric layer 901 is made of silicon oxide, silicon nitride or silicon oxynitride.

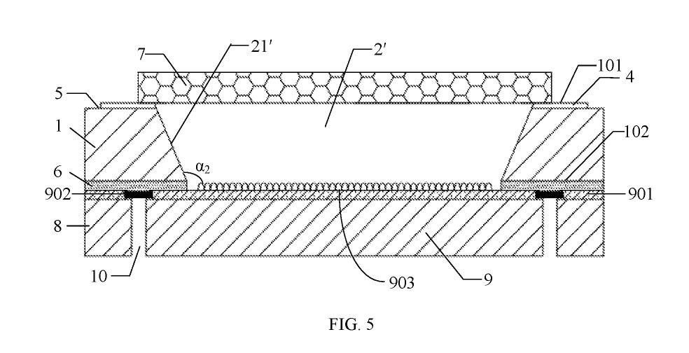

In an embodiment of the present invention, referring to FIGS. 3 and 4, channels 10 exposing the welding pads 902 are formed in a second surface of the base 8, an insulating layer 11 exposing the welding pads 902 is formed on the channels 10 and the second surface of the base 8, and a metal wiring layer 12 which electrically leads the welding pads 902 to the second surface of the base 8 is formed on the insulating layer 11 and exposed surfaces of the welding pads 902.

Preferably, a protection layer 13 is formed on the metal wiring layer 12 to prevent oxidation or corrosion of the metal wiring layer 12. One or more second openings and welding balls (not shown) are disposed in the preset positions of the protection layer 13, and the welding balls are connected to the metal wiring layer 12. Thus, the sensing region 903 of the high-pixel image sensor chip may be electrically connected to the second surface of the base 8 through the metal wiring layer 12 and the welding balls, that is, a base back of the chip is interconnected.

In an embodiment of the present invention, the insulating layer 11 is made of a high-molecular polymeric material, silicon oxide, silicon nitride or silicon oxynitride. The metal wiring layer 12 is made of Al, Ni, Au, Cu, Ti, Pt or any combination thereof. The protection layer 13 is made of a high-molecular polymeric material.

The supporting substrate 1 in the wafer level packaging structure of the high-pixel image sensor chip according to the present embodiment not only meets the requirement of the gap between the sensing region 903 and the light-transmitting substrate 7, reduces the influence of the particles of the light-transmitting substrate 7 on the sensing region 903, but also makes the plane on which the light-transmitting substrate 7 is placed be parallel or approximately parallel with the sensing area 903 as much as possible, thus the optical performances of the packaging structure is improved. The free degree of the placement of the light-transmitting substrate 7 can be increased by designing the top size of the first opening 2 to be smaller than the bottom size, and the conjunction of the thickness of the supporting substrate 1 and the inclination of the side walls 21 of the first opening 2 may reduce some undesirable phenomena such as ghost, dazzle light of the high-pixel image sensor chip. The vent groove 4 and the semi-closed channel 5 on the first surface 101 of the supporting substrate 1 can bring a good effect on the balance of the atmospheric pressure inside and outside the first opening 2.

As shown in FIG. 5, except that the top size of the first opening 2′ is larger than the bottom size, a wafer level packaging structure of the high-pixel image sensor chip according to another embodiment of the present invention is substantially similar to the wafer level packaging structure shown in FIG. 1, thus repeated description will be omitted to avoid redundancy.

Specifically, a dihedral angle α₂ of side walls 21′ of the first opening 2′ and the plane on which the sensing region 903 is located is in the range of 90°<α₂≤130°. Because the top size of the first opening 2′ is larger than the bottom size, the incident light entering the sensing region 903 may be reflected to the side walls 21′ of the first opening 2′, and reflected out by the side walls 21′, thus the probability of the reflected light reentering the sensing region 903 will be reduced, which may effectively improve optical properties and reduce the influence of some phenomena induced by the high-pixel image sensor chip, such as ghost, dazzle light, etc.

While the present disclosure has been described with reference to exemplary embodiments, it will be apparent to those skilled in the art that various changes and modifications may be made without departing from the spirit and scope of the present invention. Therefore, the above embodiments are provided for illustrative purposes only, and should not in any sense be interpreted as limiting the scope of the present disclosure.

What is claimed is:

1. A wafer level packaging structure of a high-pixel image sensor chip, comprising an image sensor chip, a supporting substrate and a light-transmitting substrate, wherein the image sensor chip comprises a base and a sensing region formed on a first surface of the base; the supporting substrate is attached to the first surface of the base and provided with a first opening penetrating through the supporting substrate at a position corresponding to the sensing region, and the sensing region is exposed from a bottom of the first opening; and the light-transmitting substrate is fixed on a first surface plane of the supporting substrate and covers a top of the first opening, and two surface planes of the light-transmitting substrate are parallel with a plane on which the sensing region is located.

2. The wafer level packaging structure according to claim 1, wherein the light-transmitting substrate has a planar size larger than the first opening and smaller than the first surface plane of the supporting substrate.

3. The wafer level packaging structure according to claim 1, wherein the light-transmitting substrate is made of IR optical coated glass.

4. The wafer level packaging structure according to claim 1, wherein side walls of the first opening are sloping.

5. The wafer level packaging structure according to claim 4, wherein a top size of the first opening is smaller than a bottom size of the first opening.

6. The wafer level packaging structure according to claim 5, wherein a dihedral angle of the side walls of the first opening and the plane on which the sensing region is located is greater than or equal to 40° and less than 90°.

7. The wafer level packaging structure according to claim 4, wherein a top size of the first opening is larger than a bottom size of the first opening.

8. The wafer level packaging structure according to claim 7, wherein a dihedral angle of the side walls of the first opening and the plane on which the sensing region is located is greater than 90° and less than or equal to 130°.

9. The wafer level packaging structure according to claim 1, wherein the supporting substrate is made of silicon.

10. The wafer level packaging structure according to claim 1, wherein a thickness of the supporting substrate is in a range of 100 μm˜500 μm.

11. The wafer level packaging structure according to claim 1, wherein the supporting substrate further comprises a second surface plane which is opposite to the first surface plane of the supporting substrate, and the second surface plane of the supporting substrate is pasted on the first surface of the base by glue.

12. The wafer level packaging structure according to claim 1, further comprising at least one vent slot, wherein the at least one vent slot is carved on the first surface plane of the supporting substrate and connects the first opening and an edge space of the supporting substrate.

13. The wafer level packaging structure according to claim 12, further comprising at least one semi-closed channel penetrating the edge of the supporting substrate, wherein the at least one semi-closed channel is formed at a periphery of the first surface plane of the supporting substrate and connected to the at least one vent slot.

14. The wafer level packaging structure according to claim 1, wherein the image sensor chip further comprises multiple welding pads which are located at a periphery of the sensing region, and the welding pads and the sensing region are electrically connected through internal metal wiring.

15. The wafer level packaging structure according to claim 14, wherein the image sensor chip further comprises a dielectric layer formed on the first surface of the base, and the sensing region and the welding pads are disposed in the dielectric layer.

16. The wafer level packaging structure according to claim 15, wherein the dielectric layer is made of silicon oxide, silicon nitride or silicon oxynitride.

17. The wafer level packaging structure according to claim 14, further comprising channels, an insulating layer and a metal wiring layer, wherein the channels are formed in a second surface of the base and expose the welding pads, the insulating layer is formed on the channels and the second surface of the base and exposes the welding pads, and the metal wiring layer is formed on the insulating layer and exposed surfaces of the welding pads and electrically leads the welding pads to the second surface of the base.

18. The wafer level packaging structure according to claim 17, further comprising a protection layer formed on the metal wiring layer.

19. The wafer level packaging structure according to claim 18, wherein the insulating layer is made of a high-molecular polymeric material, silicon oxide, silicon nitride or silicon oxynitride; the metal wiring layer is made of Al, Ni, Au, Cu, Ti, Pt or any combination thereof; and the protection layer is made of a high-molecular polymeric material.

20. The wafer level packaging structure according to claim 18, further comprising one or more second openings and welding balls which are disposed in preset positions of the protection layer, wherein the welding balls are connected to the metal wiring layer.
